(19) United States
(12) Patent Application Publication
(10) Pub. No.: US 2026/0220318 A1
(43) Pub. Date: Jul. 30, 2026

(54) A METHOD FOR REPRESENTING ON A DISPLAY AND INTERACTING WITH MULTIDIMENSIONAL AND MULTIVARIATE DATASETS CORRESPONDING TO ENVIRONMENTAL VARIABLES OF AN URBAN LOCATION

(71) Applicant: URBANMETRIX SA, Comano (CH)

(72) Inventor: Michele LEIDI, Lugaggia (CH)

(73) Assignee: URBANMETRIX SA, Comano (CH)

(21) Appl. No.: 19/147,521

(22) PCT Filed: Jan. 10, 2024
(86) PCT No.: PCT/IB2024/050252

§ 371 Date: Jul. 11, 2025

(30) Foreign Application Priority Data
Jan. 11, 2023 (CH) CH000019/2023
Aug. 2, 2023 (CH) CH000831/2023

(51) Int. Cl. G06F 30/12; G06F 30/13

(52) U.S. Cl. CPC G06F 30/12; G06F 30/13

(57) ABSTRACT

A method for representing on a display and interacting through a filtering, combination, and transformation of multidimensional and multivariate environmental datasets of an urban location (U), comprising the steps of: a) retrieving a 3D geographical dataset of the urban location with the shape of terrain, and possibly of buildings and/or vegetation; b) retrieving or computing a plurality of independent environmental scalar and/or vectorial datasets at said urban location, said environmental datasets corresponding to a plurality of environmental fields among solar radiation energy, wind velocity, noise sound pressure levels, and/or the visibility rate of a free volume/area, or of a target object; c) generating a 3D model of the urban location, based on values of said 3D geographical dataset and values of said environmental dataset; d) projecting said 3D model onto a 2D view and displaying said 2D view on a display, so as to display values from said 3D geographical dataset and values of said environmental datasets at a plurality of points; e) displaying a plurality of graphical user control elements onto said display, wherein at least one graphical user element allows to select one among at least two said environmental dataset; f) selecting one environmental dataset; g) receiving a first filtering command entered by a user with one of said graphical user control elements for defining a filtering threshold to be applied to the selected environmental dataset; h) generating a filtered 3D model where the values of the 3D model for which the filtering threshold on said environmental dataset is not reached are excluded; i) displaying a 2D projection of said first modified 3D model; j) repeating steps f) to i) for at least a second independent environmental dataset; k) combining values of two or more different filtered independent environmental datasets, so as to generate a combined environmental dataset at said location; l) generating a combined 3D model of the urban location, said combined 3D model combining values of said 3D geographical dataset and values of said combined environmental dataset; m) projecting said combined 3D model onto a 2D view and displaying said 2D view on a display, so as to display values from said geographical dataset and values of said combined environmental datasets at a plurality of points; n) receiving a filtering command entered by a user with one of said graphical user control elements for defining a filtering threshold to be applied to the combined environmental dataset; o) generating a filtered combined 3D model where the values of the combined 3D model for which the previous filtering threshold on said combined environmental dataset are not reached are not displayed; p) displaying a 2D projection of said filtered combined 3D model.

### TECHNICAL DOMAIN

The present invention concerns a method for representing and interacting with a plurality of datasets corresponding to environmental variables at an urban location.

### RELATED ART

The conception of healthy and sustainable architecture in urban settings is one of the primary challenges of our society. Physical properties related to sun, views, noise, airflows, pollution, and other environmental factors are crucial for human comfort, health, and sustainability. To fully understand these physical phenomena, it is therefore important to perform an accurate environmental analysis of the local urban context.

Over time, site analysis became a typical phase of the building design process dedicated to the study of environmental but also climatic, geographical, historical, legal, and infrastructural aspects of the site. Designers and engineers developed tools to analyze and map site-related information long before the advent of computer technologies. In relation to environmental information, a typical approach consisted in retrieving meteorological data in the form of time charts, where variables like temperature, humidity, solar radiation, wind speed, and rainfall are plotted over yearly or daily cycles.

Among these graphical tools, Sun Path Diagrams are probably the most diffused and exist in a range of different configurations according to several types of geometrical projections. Some tools, like psychometric or bioclimatic charts, additionally allow setting these climatic variables in relation with human comfort.

Nowadays many of these methods have been integrated with meteorological databases in architectural 3D modeling programs, so that, given the geographical location of a site, representations like Sun Path Diagrams, Radiation Squares or Wind Roses can be retrieved through a simple click. After the site analysis phase the architect/planner usually integrates the relevant resulting information into a graphical sketch, typically a top view, that sets the environmental features of interest in relation with the physicality of the site in terms of parcel, topography, and built environment. This representation is then often used as a starting point to develop environmental strategies during the conceptual design phase.

Generally, these graphical tools are very adequate to study the environmental resources of simple sites. In fact, if the environmental resources are distributed quite homogeneously through the site, the analysis process can be reduced to a single entity, typically the center point of the parcel.

However, if the subject of the study is a more intricate urban site, and/or located in a non-trivial topographic context, then most of these tools fall rather short, especially in the presence of close obstructions.

To address this issue many software tools have been developed. They allow the analysis of environmental resources based on digital simulations, on information on the near context and on early sketch of an architectural solution. However, these early-design building simulation-optimization software are trapped in a chicken-egg problem: a surface-based digital building sketch is always required to run an environmental simulation (related for example to sun rays, lines of sight, air flows, or noise propagation), while the aim is to conceive the building based on the results of the simulation. The related single- or multi-objective heuristic processes are thus hugely dependent on the initial constraints set by the user and can act only within very limited boundaries

Similarly, more recent AI-powered automated simulation-optimization generative solutions or AI-powered environmental building configurators are also self- and/or past-referential. Thus, even if they help to achieve some results in a faster way, they can hardly assist the users in generating really innovative and better solutions because they remain deeply linked to the initial definitions and constraints set by the users and thus to old design and decision paradigms. Additionally, AI-based solutions are often based on black-box systems and the user is therefore not fully informed on the reasons that should make the proposed solutions performant.

Software attempts have been made to try to step back from the ‘early-design’ phase of the recent software solutions to the ‘pre-design’ phase of the traditional graphical tools. Some of these attempts are based on a bottom-up approach, where the values of the different environmental variables are determined for a volumetric set of sensor points representing the empty space of a site. However, these attempts have failed to produce breakthrough solutions essentially because of a lack of simple way to deal with a very elevated degree of variates and dimensions.

To simultaneously address the need for a joint evaluation of several environmental resources in their full temporal and spatial dimensions with the ambition of enabling the evaluation of the key potentials of urban sites directly from the specificity of the resources present in the empty space-time of every different site, a comprehensive volumetric site analysis methodology has been proposed. This technology is based on the recent availability of very-high-resolution 3D geographical datasets information on the accurate shape of terrain, buildings, and vegetation. Based on this data additional environmental datasets can be retrieved or computed trough simulation and, added to this geographical dataset, and then displayed to the user through a 3D visualization framework.

In this visualization framework, a series of volumetric environmental fields are then represented in 3D. Typical variates of such environmental datasets are for example related to solar radiation, views, wind, and noise. The goal of this kind of environmental information is to provide key suggestions that perfectly fit to the local conditions in relation to goals of architectural design, construction engineering, energy technologies, land planning, urban planning, and real estate. It is thus a technical tool used during the pre-design phases of a project.

However, this technology still fails to deliver a practical usability because of the overwhelming amount of the generated data and because of the complexity of its representation and interpretation. The results generated through the described process can have both a scalar (v) and vectorial (vx, vy, vz) structure, and compose complex multidimensional (x, y, z, t) and multivariate (v, u, w, . . . ) datasets that are of very difficult interpretation. Additionally, given the amount of information and the multiplicity of the involved parameters, a direct, comprehensive, and interlinked understanding of these datasets is out of human reach and the correlations among the different variates, and their parameters, with the goals of the investigations, are extremely difficult to establish.

Here below we list some identified existing prior art document in related fields.
US2022/0198084A1 is related to a solar panel positioning software. It describes heatmaps of irradiance at various locations, for example on a roof. Thresholds can be entered on a GUI so that the system recommend one or more suitable panel placements. The document fails to consider the shape of the terrain and is therefore not adapted to mountainous regions where mountains project shadows on buildings.
Moreover, it fails to consider other environmental datasets than solar irradiance.
US2021/0110156A1 is quite similar to US2022/0198084A1, although it does consider the impact of adjacent building, trees etc. on solar irradiance.
L. Jiaming et al, “An open-source 3D solar radiation model Integrated with a 3D, geographic Information System”, ENVIRONMENTAL MODELLING & SOFTWARE, 10 Dec. 2014 is another document related to modelling of solar irradiance only.
Murshed Syed Monjur et al., “Modelling, validation and Quantification of Climate and other Sensitivities of Building Energy Model on 3D City Models” does consider more than one environmental dataset, but fails to disclose filtering data, especially when the amount of data to be displayed is very high.
Giraldo Gabriel et al., “Towards a sensitive Urban Wind Representation in Virtual Reality”, Apr. 6, 2022 describes a representation of wind vectors in a virtual volume.

### SHORT DISCLOSURE OF THE INVENTION

Most of the existing prior art is thus related to the analysis of one single environmental parameter, often related to the surface of a 3D roof/building/city model, that is sometimes used to optimize the placement of a component on an existing building or building design.

An aim of the present invention is the provision of a new method for displaying and interacting with complex and large multidimensional and multivariate datasets corresponding to environmental variables at an urban location, which offer crucial advantages for the manipulation of such datasets.

According to the invention, this aim is attained by the object of the attached independent claims, and further described in the dependent claims.

With respect to what is known in the art, the invention provides the advantage that a high level of dimensions and variates, as well as their potential correlations and/or their relation to specific goals of a project, can be easily manipulated, combined, reduced, processed and displayed to extract useful information.

According to one aspect, the invention is related to a method including the steps of claim 1.

The method thus provides an iterative, interactive, multi-level, and interrelated filtering and combination method for processing multidimensional environmental datasets.

The method is multi-level because it allows to filter datasets both at the level of independent environmental datasets, and at the level of combined environmental datasets.

The filtering can also be interrelated because the effects of these different filters applied at multiple levels can be directly combined, and constraints of thresholds, averages, projections, etc. can be updated in real time along to filtration process to generate the final result.

The method may include the following characteristics:
1. The environmental variables of the method are related to empty represented by 3D sensor points;
2. The analysis of multiple layers of environmental information;
3. The combination of such multiple environmental variables; and/or
4. The filtering of the combined datasets.

The unexpected hidden patterns revealed by this method allow to generate very impactful added values that are very specific to the architectural, engineering, planning, or real estate goals of the user. Examples of such goals can be the definition of the forms of buildings, their exterior surfaces, their internal subdivisions, questions of energy and plants, the planning of urban areas, the identification of parcels with specific environmental properties, or real estate valuations.

Depending on the environmental datasets, this method may be used for representing for example the spatial points at an urban location that have concurrently the highest solar radiation energy, the lowest wind velocity, the lowest traffic noise sound pressure levels, and the highest or best visibility. This could be used for example by architects and urbanists for spotting a good site, or planning an urban development, a construction, or a renovation. In another use case, this could also be used for example for planning the installation of photovoltaic panels on a building optimising the production of solar energy, while concurrently using the PV surfaces as noise or solar shelters and also avoiding to place PV surfaces at locations exposed to strong wind. In another use case, this could be used to position balconies in places which have concurrently good evening solar access, high lake view rates, low evening traffic noise, and airflows with speeds within an ideal range.

For the purpose of the present disclosure, a multidimensional dataset is a set of data values that can have both a scalar (v) and vectorial (vx, vy, vz) structure and a plurality of dimensions, such as (x,y,z,t) for example.

For the purpose of the present disclosure, a multivariate dataset is a set of data values of different physical properties (u, v, w), possibly quantified with different units of measure.

For the purpose of the present disclosure, environmental datasets are datasets for representing variables of the environment, such as solar radiation, wind speed and direction, visibility, noise levels, etc.

For the purpose of the present disclosure, a scalar dataset is a set of scalar values, such as sampled and digitized values of one environmental field representing an area or a volume of interest.

For the purpose of the present disclosure, a vectorial dataset is a set of vectors, such as sampled and digitized vectors of one environmental field representing an area or a volume of interest. The value of each vector depends on all its components, and thus both on its module and direction.

For the purpose of the present disclosure, combining values of two different environmental dataset can involve performing a logical and/or arithmetical combination between each pair of corresponding scalar or vectorial values from the two datasets.

Since the datasets are multivariate, the values in different environmental datasets might have different units of measure. For example one dataset corresponding to scalar values in a solar radiation energy field might include values in J/m2/y while a second dataset corresponding to a wind velocity field might include values reported in m/s.

Therefore, the combined environmental dataset might include, for each point, a value which is a logical and arithmetical combination between values from two different datasets, possibly comprising values expressed in different units.

The combination between values reported in different units might include a step of normalizing the values, so as to convert them in a number without any unit. In one embodiment, combining values might include a step of normalizing each value, for example by reporting them in a range from 0 (minimum value) to 100 (maximum value), or any other normalized interval.

Combining values might include a step of weighting each value, for example by multiplying the scalar and/or vectorial value at each point with a weighting scalar factor. The weighting factor might be set by the user, or predefined.

Combining values might include a step of performing a logical combination, such as an AND, OR, XOR or NOT combination.

Combining values might include a step of performing an arithmetical combination, such as a multiplication, and addition, an averaging, a difference, etc., between values from two or more different environmental datasets.

Combining the values of different environmental datasets, that might have been previously filtered, may also allow such values to simply influence concurrently different parts of a joint 3D visual representation without the values being mathematically combined.

The filtering may be entered with graphical user control elements, such as any control on a graphical user interface (GUI), such as a button, a slider, a rotating knob, a text entry-box, etc.

At least some of the different 3D models might be time-dependent models, i.e. dynamic models, where the values at each point can vary in function of time (hour of the day, month of the year, etc.).

The method may include a step of receiving a specific time entered by the user, and displaying a modified view with values at each point corresponding to the values at that specific received time.

The method may include a step of receiving a time interval entered by the user, and displaying a modified view with values at each point corresponding to an average or a sum during said time interval of values at this point.

The method may include a step of receiving a coordinate interval entered by said user, and displaying only the values of the environmental datasets for points that lay within said interval. The coordinate interval might include a range for one or several dimensions (x,y and/or z).

The method may include a step of receiving a resolution value selected by said user, and adapting the spatial distance between the points depending on said resolution.

One filtering threshold may be a numerical threshold applied to the scalar values of the dataset, or to the modules of the vectors in a vectorial dataset.

One filtering threshold may be a numerical threshold applied to the number of units of area/volume, located at the position of each sensor point, to be displayed.

One filtering threshold may be a lower boundary, an upper boundary, or a range between a lower boundary and an upper boundary.

One filtering threshold may be applied to the whole area or the whole volume, or it may be applied independently to specific sub-portions of them, like smaller areas of a bigger area (e.g. independently to municipalities of a bigger region) or smaller volumes of a bigger volume (e.g. independently to all points located at the same horizontal height of a volume).

One filter may involve the reduction of the area(s)/volume(s) of interest, to the borders that wrap that area(s)/volume(s), using for example convex and/or concave hulls (e.g. displaying the border of an area of land, the border of a building volume, or the borders of floor slab, etc.).

Other types of filters may be applied. For example, in a vectorial field, one threshold may be used for filtering only vectors pointing into one specific direction, or range of directions.

Other filters may replace the displayed scalar values, modules, or directions, with the average values across areas, volumes, and/or time intervals.

Other filters may allow to decide whether to display, for example with colour or grayscale gradients, the scalar value, the module of the vector, or the ratio between these two values.

The method may include the steps of projecting vectors of the vectorial dataset along one specific direction, or over a specific plane.

For example, this method might include projecting the vectors along their average direction.

For example, this method might include projecting the vectors on an horizontal plane. This could for example allow to orient a vertical surface such as that of a window or a façade.

For example, this method may comprise a step of projecting the vectors of one of said vectorial dataset on a vertical plane having a horizontal orientation defined by the user. This could for example allow to retrieve the ideal vertical tilt of photovoltaic panels for an urban building project that has an already defined/constrained orientation of the main building façade.

One of said environmental datasets may represent the visibility in different directions. The free-visibility from one point may be indicated as a percentage of an area or volume around that point that is unobstructed. For example as a fraction of a horizontal circle around the point, as a fraction of a sphere, or as a fraction of a spherical sector.

The target-visibility may be represented by the rate between the field of view occupied by a target object and the full spherical field of view. For example, a view on a landscape with water objects is usually preferred to a view on a landscape with industrial objects.

The method may include a step of filtering points in one of said combined datasets according to the values of their neighbouring points.

Control elements could be used to filter points not only to their own values but also according to the values of their neighboring points (e.g., selecting only elements for which a certain condition is valid for at least 2 of their neighboring points).

The method may comprise a step of receiving a command entered by a user with said graphical user control elements for hiding points that could be altered by future obstructions inside the volume itself, i.e. keeping only the points on the boundaries of the volume that will have constant values independently to what will be potentially inserted inside the volume.

The method may comprise a step of receiving a command entered by a user with said graphical user control elements to display only points that are close to an object specified by the user, i.e. keeping only the points that are under a given distance (e.g. 1m) from the surfaces of said object.

The method may comprise a step of saving and/or recovering a set of selection, filtering, and/or combination parameters as presets. Presets can thus then be easily retrieved and applied to a different environmental dataset and/or a different urban location.

The graphical user interface may comprise buttons that allow the user to visualize the geometrical operators that have been used to generate the results of the environmental datasets. These geometrical operators, that can assist the user in the filtering process, can for example comprise sun-rays, lines-of-sight, wind-flow-lines, sound-propagation-lines, target-objects, obstruction-objects, emitting-objects, intersection-points, reflection-points, and diffraction-points.

The graphical user interface may comprise controllers to display single spatial sectors of a set of said geometrical operators (e.g., rays or multi-lines), and/or display also the results of the aggregation of a selection of such sectors.

The graphical user interface may comprise 2D camera images of the 3D model, that can be constructed with different types of projections and from different points of view, that allow to visualize detailed information related to the shape and/or values of each of these said geometrical operators and assist the user in the interpretation and/or filtering process.

The graphical user interface may comprise 2D colour or grayscale heatmaps that allow to visualize detailed information related to the shape and/or values of each of these said geometrical operators and assist the user in the interpretation and/or filtering process and in the identification of global and/or local maxima and minima in the values of said operators. 2D sliders laid on top of these 2D camera images or heatmaps may assist the user in selecting a specific geometrical operator or a range of such operators.

Filtering transformations may allow the user to transform the data used to generate abstract or semi-abstract visual representations into refined schemes related to more concrete suggestions related to the design of constructions. Said 3D design-suggestions can be based on cellular schemes (i.e. composed by an aggregation of multiple cells of space representing for example single rooms), and/or single-building schemes (that represent a sketch at the level of an entire building), and/or multi-building schemes, and/or infrastructural schemes.

The invention is also related to a computer program product comprising instructions which, when the program is executed by a computer, cause the computer to carry out the method of one of the previous claims.

### SHORT DESCRIPTION OF THE DRAWINGS

Exemplar embodiments of the invention are disclosed in the description and illustrated by the following drawings:

FIG. 1 illustrates a 2D representation of a 3D volume corresponding to geographical dataset of a urban location with the shape of terrain and buildings.

FIG. 2 illustrates the same representation with a plurality of graphical user control elements to select: an environmental dataset to be displayed, a combination between environmental datasets to be displayed, filters to be applied, and the type of representation to be used;

FIG. 3 illustrates a 2D representation of a terrain surface from a 3D geographical dataset of an urban location.

FIGS. 4a-4e illustrate various 3D visualization elements for representing environmental values on a 2D view.

FIGS. 5a-5d illustrate different methods for the reduction of the directional parts of tensors.

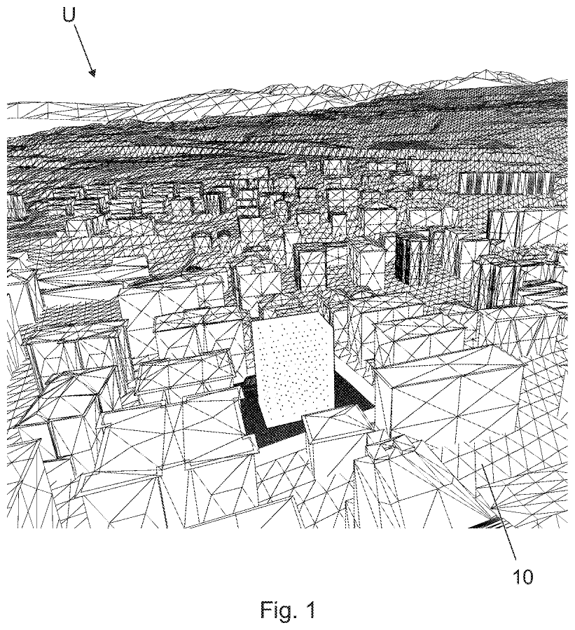

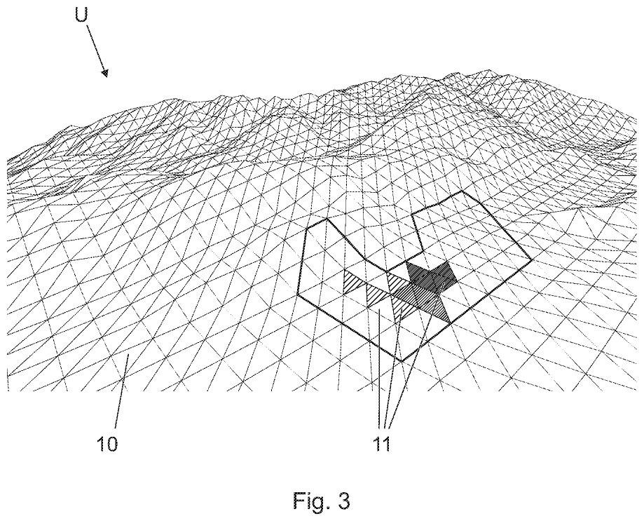

Geodata source for FIGS. 1 to 3: Swiss Federal Office of Topography swisstopo.

### DETAILED DESCRIPTION OF THE INVENTION

For the purpose of the present disclosure, an urban location U denotes any site or area where an environmental analysis needs to be or has been performed with the aim to retrieve decision and/or design suggestions in relation to the position, amount, size, direction, and/or form of a specific aimed intervention. An urban location U can denote a 2D or 3D area of land or the 3D volume of a site (see FIG. 1). The aimed interventions at the urban location are typically related to:
land planning, urban planning, or urban design (zoning, urban development plans, public spaces and infrastructure, mobility infrastructure, energy plants, etc.);
real estate strategies and projects (site spotting, valuation, design of large urban developments, distribution of uses, functions, buildings, or living units, etc.);
Position, orientation, proportion, and form of buildings;
external building surfaces and building components (transparent surfaces, windows, openings, facades, roofs, external shadings, balconies, wind shelters, solar shelters, noise shelters, views shelters, photovoltaic surfaces, thermal surfaces, wind turbines, ventilation in/out-lets, heat exchangers, etc.;
distribution of uses and functions inside buildings (shape and position of living units, shape of floorplans, sizing of rooms, etc.).

According to one aspect, the method of the invention can be used at a pre-design or pre-decision stage, i.e., as a simulation method adapted to generate and display a 3D model of an urban location U taking into account environmental data. Although an original model of the urban location may include existing and planned objects, the method does not require the planned urban object to be modelised in advance; rather, it can be used before the conception process, to retrieve crucial environmental suggestions to be used to start the conceptual process with new means. The urban location U can thus be any free space in a city or abroad, or also an existing space or area to be modified, renovated, rebuilt and so on.

According to one aspect, the method relies on a discretization of the unoccupied space of a site/area into a matrix of sensor points, or voxels, 11. At each of these points, different physical properties of the environment (such as sun radiation, airflow, noise, visibility, etc.) are computed or retrieved. Those environmental values have either a scalar (v) or a vectorial (Vx, Vy, Vz) structure, are stored as datasets according to the four spatiotemporal dimensions of the area/volume (x, y, z, t). This environmental data is then combined with geographical model of the location into a 3D model, which is made accessible to the user through visualization on a display. Different values at each sensor point may be represented for example with different colors, with numbers, with arrows etc. (not shown on FIGS. 1 to 3). The urban location is defined at least by the 3D shape of the ground (that in some cases may be flat) can be completed by the 3D shape of buildings and/or the 3D shape of relevant vegetation.

The urban location may be represented by a 3D geographical dataset, i.e., a set of numerical values representing the shape of terrain 10, and possibly buildings and/or vegetation. The 3D geographical dataset representing the urban location may be gathered from geodata providers, retrieved from cartographic databases, from architect plans, and/or from 2D or 3D images. This dataset may represent at least the shape of terrain. Existing buildings and/or projected buildings and/or vegetation may also be represented by this dataset.

For example, the 3D geographical dataset may represent a three-dimensional profile of the ground 10, comprising hills, inclinations, slopes, mountains, and any landforms that could be considered. The presence of natural or artificial objects such as trees, rivers, buildings, and infrastructure already present at the urban location, can also be considered.

An example of representation on a display of an urban location U of a 3D geographical dataset is shown on FIG. 1. In this example, the 3D geographical dataset is represented by a mesh of triangular surfaces. The 3D geographical dataset itself is stored as a set of values in computer memory, for example a set of sampling values.

The method of the invention also requires a plurality of environmental scalar and/or vectorial datasets at the urban location. The environmental datasets are numerical representations of a plurality of environmental fields such as solar radiation energy, wind velocity, noise sound pressure levels, and/or the visibility rate of a free volume/area, or of a target object. The environmental datasets can by static, or dynamic, i.e., changing over time.

The environmental datasets can be already available, and for example retrieved from a database. They can be physically determined on site, for example by appropriate observations or measures. They can be calculated, for example with known simulations or prediction tools. Each environmental dataset includes or can be used for determining the value of an environmental field at a plurality of points at the urban location.

Different environmental datasets may correspond to different environmental fields such as the yearly, monthly, or hourly solar radiation energy or time, and/or the wind speed, direction, pressure, turbulence intensity, and/or the noise sound pressure levels, and/or the visibility of open space (free portions of volumes or areas around an observation point), and/or the visibility of target objects (lakes, green areas, monuments, ugly industrial areas, etc.). These environmental datasets can be obtained for a single context or for multiple contextual scenarios (current or future, with or without vegetation, etc.).

Some environmental datasets may correspond to a set of environmental scalar values at different points of the area/volume. For example, one environmental dataset may indicate the noise level at different points of the area/volume.

Some environmental datasets may correspond to a set of environmental vectorial values at different points of the area/volume. For example, one environmental dataset may indicate the amplitude and direction of wind or solar energy at different points of the area/volume.

Different datasets may indicate values in different units. For example, a noise level may be indicated in decibels; a solar energy in J/m2/y; a wind speed in m/s; and a visibility in percentage.

The values of environmental datasets can be normalised, for example by representing it on a scale from a minimum value (for example 0) and a maximum value (for example 100). Normalisation allows the combination of datasets with values having different units of measure, as will be described.

To perform a combination the values of the different environmental datasets can be weighted, by multiplying them with a scalar weighting value. The weighting value can express the importance of one specific dataset in relation to the other ones. The weighting value applied to one specific dataset may be predefined. It may be defined by the user. It may be saved in or recovered from a preset.

The values of different environmental datasets, that might have been previously filtered, can also be combined by the fact that they influence concurrently different parts of a joint visual representation without being mathematically combined. This joint display might involve priority rules.

Each one of the environmental datasets can be selected and independently filtered, manipulated, and displayed. The filtering process can be iterative. For example, a first filter may be applied to the environmental dataset, so as to produce a filtered 3D model. A second filter can then be applied on the filtered 3D model, resulting in a second filtered 3D model on which two different filters have been applied.

Two different environmental datasets can be combined into one combined environmental dataset, by combining the possibly normalised and possibly weighted values of each dataset at each sampling point of the area/volume. The user can select which environmental datasets he wants to combine. At each sampling point, the combined environmental dataset thus stores a value depending on the combination of different environmental variates. For example, the combined environmental dataset may indicate at each point one combined value that indicates, on a normalised scale, the amount of both solar energy and wind velocity.

In another example two different environmental datasets that have been previously filtered are simply jointly displayed contributing independently to the overall visual representation.

As for the original environmental datasets, the combined environmental datasets can be separately and/or independently filtered, manipulated and displayed. The method is thus multi-level because it allows to filter and possibly transform datasets both at the level of independent environmental datasets and at the level of combined environmental datasets. The interactive filtering process can also be iterative. Moreover, the filtering can also be interrelated, i.e. a filter applied to one environmental dataset can automatically have an effect on any other filter applied to such dataset, or the combined environmental dataset into which this environmental dataset is combined.

Additionally, some predetermined basic parameters corresponding to characteristics of one analysis one wants to perform or one intervention one aims to realize may be entered. For example, the number of floors of an urban building to be realized, or the minimal surface of the ground to be occupied, or the main orientation of an urban object, or the minimal surface of solar panels to be distributed, or the maximal acceptable sound levels. Such basic parameters may be determined by fundamental project requirements, by project constraints, by regulation, can result from specific standards, may arise from the client requests, or originate from any source. Such basic parameters thus appear as original constraints that should be considered in the evaluation of the urban location.

The 3D geographical dataset and the values of the environmental datasets, including the combined environmental datasets, can be combined so as to generate a combined 3D model of the urban location. The combined 3D model combines values of the 3D geographical dataset and values of the environmental datasets at different points through the area/volume of the location. Thus, the combined 3D model of the location indicates geographical parameters of the environment (ground, building, vegetation, etc.) and one or a plurality of environmental values, and/or combined environmental values, at a plurality of points of the area/volume.

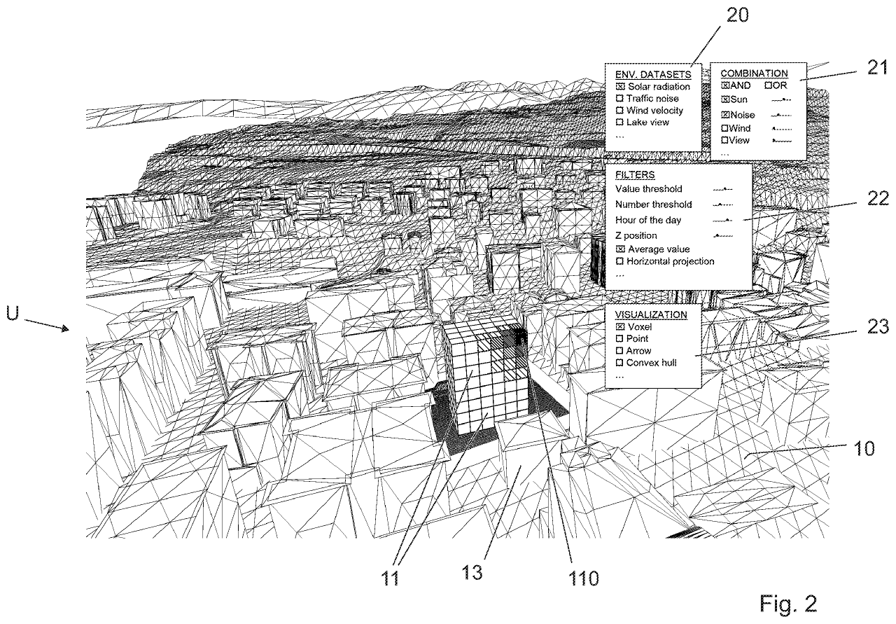

The 3D model, or combined 3D model, is then projected onto a 2D view, which can be displayed on a display, such as a computer display, as shown on FIG. 2. The interface may include graphical user interface elements 20-23 to select, combine, filter, and transform the visualisation and other commands to set the 2D view, for example by zooming, rotating, displacing, etc. the projection plane. In the example of FIG. 2, the underlying 3D geographical dataset includes the ground 10, the buildings 13, and a grid of orthogonal sensor points represented by voxels 11, while one environmental dataset is represented on this view with grayscale levels or textures 110 at each point or voxel 11.

Such a visual representation allows for example to easily identify the most sun irradiated parts of the urban location, or at a specific time of the day or as an average over a time interval. For example, the solar radiation at in summer time can be represented according to such a graphical representation.

The displayed 2D view thus shows values from the geographical dataset (the terrain and possibly the buildings and/or vegetation of the environment) and the values or directions of the selected environmental datasets, or combined environmental datasets, at a plurality of points.

The display can be part of a computer comprising a keyboard, and/or other input means, a processor, a memory, and a computer program for computing and representing the 2D view. The computer program includes a graphical user interface allowing the user to select the environmental datasets or combined environmental datasets he wants to display, to manipulate them and to filter them.

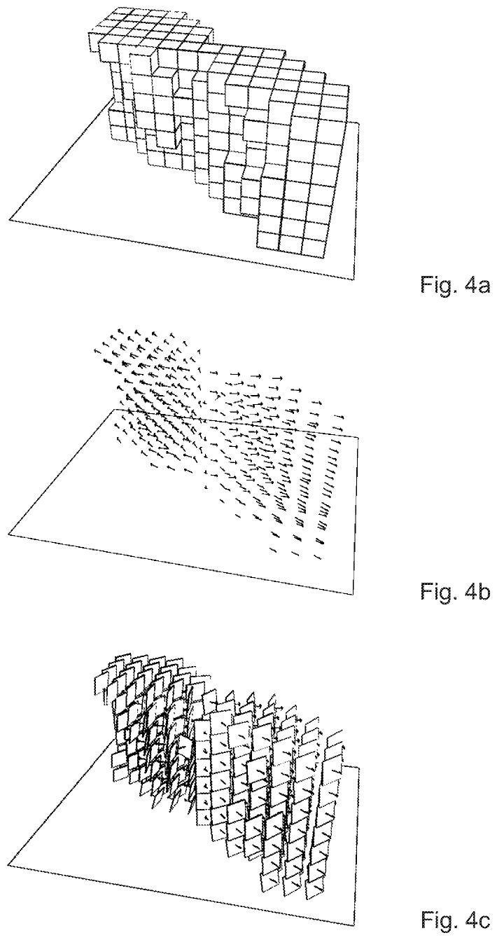

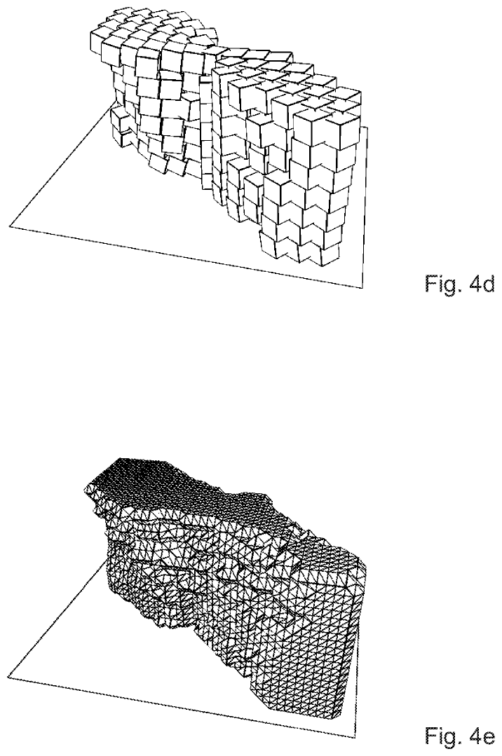

Environmental datasets (including combined environmental datasets) may be represented with various visualization elements 23 on the 2D view. For example, scalar values and the module of vectorial values may be displayed with coloured voxels (FIG. 4a), points, polygonal hulls, or surfaces, with levels of greys, or with numbers next to each sampling point or voxel 11, etc. The direction of vectorial values may be displayed with arrows and/or oriented surfaces, (FIG. 4b, respectively 4c), or with oriented volumes (FIGS. 4d and 4e), etc.

The 3D model, and the combined 3D model, may include a very large number of sampling points, for example more than 1000 points or more than 100′000 points. A plurality of environmental values may be represented at each point, including scalar and/or vectorial values. The simultaneous 2D projection of this 3D model on a display is therefore impossible, and multiple parallel or simultaneous 2D projections would be extremely difficult to interpret, since there are a huge number of scalar values and/or vectors to be observed. There is therefore a need for reducing the amount of environmental values to be displayed and a need to correlate the content of different variates and different dimensions among each other and also to correlate their content with the requirements and constraints of the current analysis.

A first way of reducing the amount of environmental values to represent is to increase the sampling steps, i.e. reduce the number of sampling points. Reducing the sampling resolution may however result in a less accurate representation of the 3D model. A graphical user interface command element (not shown) may be used for selecting the resolution.

Another way of reducing the amount of environmental values to represent is to select the environmental datasets to be represented, and to exclude other environmental datasets. As an example, on FIG. 2, the graphical user interface comprises one element 20 for selecting among the following datasets solar radiation; noise level; and wind speed the one that need to be computed and displayed.

Another way of reducing the amount of environmental values to represent is to combine different environmental datasets into one combined environmental dataset, thus reducing the amount of visual elements to be displayed. As an example, on FIG. 2, the graphical user interface may comprises one element 21 for selecting the logics of the combination and the environmental datasets to be combined, so as to represent with a single visualization element the combined value at each point. Environmental datasets of different types, having values in different units of measure, can be combined. Many other combinations than the ones indicated in this example are possible. Moreover, weighted combinations can be defined on the user interface, for example in order to give more weight to one environmental dataset than to another one.

Another way of reducing the amount of environmental values to represent is to filter environmental datasets, or combined environmental datasets, so as to display only the values that meet the filtering conditions. As an example, on FIG. 2, the graphical user interface comprises one element 22 for selecting and/or controlling the filters to be applied to the selected environmental dataset or combined environmental dataset. The filters to apply to environmental datasets, or combined environmental datasets, can be associated with any type of graphical user interface controller such as a button, a slider, a rotating knob, a text entry box, etc.

The filtering may be based on a threshold, so that only values which are higher or lower than a threshold will be displayed. A special type of threshold based filter are Boolean filters for Boolean values; for example, one can choose to display only Boolean environmental values which are true, or values which are false.

Threshold based filters can be applied to scalar values. Threshold based filters can also be applied to vectorial values. In this later case, a scalar threshold can be applied to the module of the vector—for example to display only the values for the points in the datasets for which the wind speed, or any other vector module, is higher than a given threshold—and/or to its direction—for example to display visualization elements only for those points where the wind blows into one specific direction, or range of direction.

One filtering threshold may be a numerical threshold applied to the scalar values of a scalar dataset, to the modules of the vectors of a vectorial dataset, or to the number of sensor points (and the related voxels, oriented surfaces, arrows, etc.) to be displayed.

One filtering threshold may be applied globally to the whole area/volume of intertest, or it may be applied independently to specific local portions of that area/volume. Vectorial fields values require a lot of computation effort for representing them on a display. It is therefore technically essential to reduce the amount of vectorial information and to extract only the useful components.

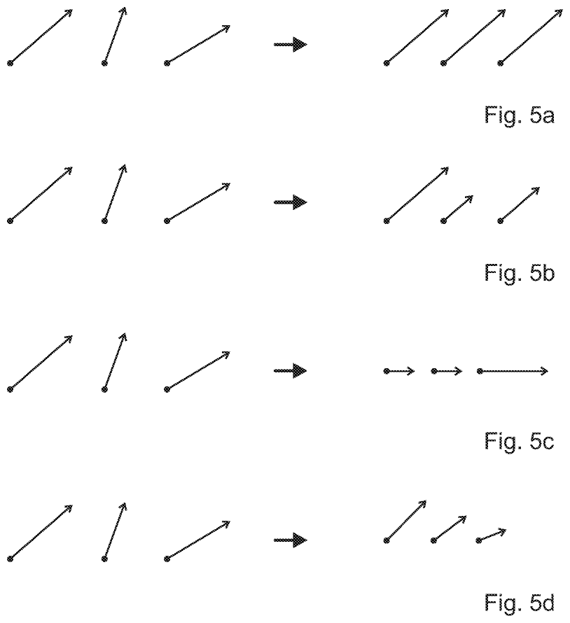

Different vectors can be averaged, as illustrated in a 2D reduction on FIG. 5a. In this example, three different vectors pointing in different directions are replaced with vectors pointing in the average direction, and of average length. The program can also then represent only one of those averaged vectors, instead of representing them all.

Different vectors can also be projected onto a defined direction, as illustrated in FIG. 5b. In this example, three different vectors pointing in different directions are replaced with the projection of each vector on their average direction. In another case such vectors could be projected on the horizontal plane as illustrated in FIG. 5c, for example to retrieve a suggestion for the horizontal orientation of a an object to be distributed/dimensioned that will in any case vertical such as it is typically the case for example for a window or a wall.

Different vectors pointing in different directions can be also projected on a vertical plane defined by an horizontal orientation given by the user for example to determine the vertical inclination of a photovoltaic panel to be placed on a facade with an already predetermined horizontal orientation, as illustrated on FIG. 5d.

This projection might be used for example for alignment of photovoltaic panels on a building. Imagine that the orientation of the main facade of a future building is already determined (for example aligned along a main street). Such a filter allows to provide this specific azimuthal orientation angle (angle of the street on the horizontal plane) via the GUI and then to project the vectors on a vertical plane that is perpendicular to this main facade. This projection allows to determine the ideal elevation angles (angles on this vertical plane) that one have to tilt upwards the photovoltaic panels if one wants also them to stay horizontally aligned with the facade (i.e. have two edges parallel to that façade).

The selection of environmental datasets to display, their combination, and their filtering and their transformations offer thus powerful means for reducing the amount of displayed data. While still providing the relevant information that is needed for the user when he plans for example a new construction at a location or he tries to identify an ideal location within an area of territory. However, it is often difficult to decide in advance which filters and combinations should be applied in a particular situation and project.

In order to facilitate this task of selecting the best filters and combinations, the method thus provides an interactive and iterative filtering where a first filtering command is entered by the user, the resulting filtered 3D model is computed and a corresponding 2D view is displayed, and a second filtering command (or a modification of the first one) can be entered by the user and applied, so as to compute a second filtered 3D model and to display a new 2D view. This interactive and iterative filtering method is also multi-level with a final output resulting from the application of a first filtration level on independent environmental datasets (pre-combination) and a second filtration level on the combined environmental dataset (post-combination). The effect of the different filters at different levels can also be interrelated in the sense that the result will depend on the reciprocal and combined effect of the entire set of filters applied to the selected environmental datasets.

Some of the datasets may be dynamic and vary in time, such as the hour of the day, the month of the year, the season, etc. The method may include selecting a specific time and displaying a modified view with values or directions at each point corresponding to the values or directions at that time. Alternatively, or in addition, the user can enter a time interval, so that the average or the addition of values at each point during said time interval will be computed and displayed.

The user can enter a coordinate interval, such as a range for one of the coordinates X, Y or Z. Only the values of said environmental datasets for points within that coordinate interval will then be displayed. For example, a user may decide to display the solar energy only on the highest level of a volume to verify where solar panels could be placed on a roof.

It is also possible to apply one filtering command to only one such coordinate interval or even to a single lower or upper boundary.

1. A computer-implemented method for representing on a display and interacting through a filtering and combination of multidimensional and multivariate environmental datasets of an urban location (U), comprising the steps of:
a) retrieving a 3D geographical dataset of the urban location with the shape of the surface of a terrain, and possibly of buildings and/or vegetation;
b) retrieving or computing a plurality of independent environmental scalar and/or vectorial datasets at said urban location, said environmental datasets corresponding to a plurality of environmental fields among solar radiation energy, wind velocity, noise sound pressure levels, and/or the visibility rate of a free volume/area, or of a target object;
c) generating a 3D model of the urban location, based on values of said 3D geographical dataset and values of said environmental datasets;
d) projecting said 3D model onto a 2D view and displaying said 2D view on a display, so as to display values from said 3D geographical dataset and values of said environmental datasets at a plurality of points;
e) displaying a plurality of graphical user control elements onto said display, wherein at least one graphical user element allows to select one among at least two said environmental datasets corresponding to two different environmental fields;
f) selecting one environmental dataset
g) receiving a first filtering command entered by a user with one of said graphical user control elements for defining a filtering threshold to be applied to the selected environmental dataset;
h) generating a filtered 3D model where the values of the 3D model for which the filtering threshold on said environmental dataset is not reached are excluded;
i) displaying a 2D projection of said filtered 3D model;
j) repeating steps f) to i) for at least a second independent environmental dataset corresponding to a different environmental field;
k) combining values of two or more different filtered independent environmental datasets, so as to generate a combined environmental dataset at said location;
l) generating a combined 3D model of the urban location, said combined 3D model combining values of said 3D geographical dataset and values of said combined environmental dataset;
m) projecting said combined 3D model onto a 2D view and displaying said 2D view on a display, so as to display values from said geographical dataset and values of said combined environmental datasets at a plurality of points;
n) receiving a filtering command entered by a user with one of said graphical user control elements for defining a filtering threshold to be applied to the combined environmental dataset;
o. generating a filtered combined 3D model where the values of the combined 3D model for which the previous filtering threshold on said combined environmental dataset are not reached are excluded;
p) displaying a 2D projection of said filtered combined 3D model.

2. The method of claim 1, wherein combining values of two different environmental datasets includes:
normalising the values of two said different environmental datasets; and/or
weighting the values of the first and second of said two different environmental datasets; and/or
applying a logic and/or arithmetical combination between said weighted values.

3. The method of claim 1, wherein said 3D models are time-dependent models, the method comprising a step of receiving a specific time entered by said user, and displaying values or directions at each point corresponding to the values at that specific time.

4. The method of claim 1, wherein said 3D models are time-dependent models, the method comprising a step of receiving a time interval entered by said user, and displaying values at each point corresponding to an average or addition during said time interval of values at this point.

5. The method of claim 1, comprising a step of receiving a coordinate interval entered by said user, and displaying only the values of said environmental datasets for points within said interval.

6. The method of claim 1, wherein one filtering threshold is applied to display only to one sub portion of said volume or area.

7. The method of claim 1, wherein one said threshold is a numerical threshold applied to the scalar values of the dataset or to the modules of the vectors in a vectorial dataset.

8. The method of claim 1, wherein one said threshold is a numerical threshold applied to the number of units of area or volume, located at the position of each sensor point, to be displayed.

9. The method of claim 1, wherein one said one filtering threshold is a lower boundary, an upper boundary, or a range between two lower and upper boundaries.

10. The method of claim 1, wherein one said filtering threshold is applied to the whole area or to the whole volume, or is applied independently to specific sub-portions of them.

11. The method of claim 1, wherein one said filter involves the reduction of the area(s)/volume(s) of interest, to the borders of the area(s)/volume(s).

12. The method of claim 1, wherein one filter allows to decide whether to display with colour or grayscale gradients the scalar value, the module of the vector, or the ratio between these two values.

13. The method of claim 1, comprising the steps of:
projecting vectors in one of said vectorial dataset along one specific direction or plane.

14. The method of claim 1, comprising a step of projecting the vectors of one of said vectorial dataset on a horizontal plane, or on a vertical plane having a horizontal orientation defined by the user.

15. The method of claim 1, wherein one of said environmental dataset corresponds to the free visibility from each point of the dataset in different directions.

16. The method of claim 1, comprising a step of filtering points in one of said combined dataset according to the values of their neighbouring points.

17. The method of claim 1, comprising a step of receiving a filtering command entered by a user with said graphical user control elements for averaging or adding scalar and directional values of said combined environmental datasets across areas, volumes, or time intervals.

18. The method of claim 1, comprising a step of receiving a command entered by a user with said graphical user control elements for hiding points that could be altered by future obstructions inside the volume itself, i.e. keeping only the points on the boundaries of the volume that will have a constant values independently to what will be potentially inserted in the volume.

19. The method of claim 1, comprising a step of receiving a command entered by a user with said graphical user control elements to display only points that are closer than a given distance to an object specified by the user.

20. The method of claim 1, wherein combining values of two different environmental datasets involves performing a logical and/or arithmetical combination.

21. The method of claim 1, comprising a step of saving and/or recovering a set of selection, filtering, and/or combination parameters as presets.

22. The method of claim 1, comprising a graphical user interface with buttons that allow the user to visualize the geometrical operators that have been used to generate the results of the environmental datasets.

23. The method of claim 1, comprising a graphical user interface with 2D camera images of the 3D model, that can be constructed with different types of projections and from different points of view, that allow to visualize detailed information related to the shape and/or values of each of these said geometrical operators and assist the user in the interpretation and/or filtering process.

24. The method of claim 1, comprising a graphical user interface with 2D colour or grayscale heatmaps that allow to visualize detailed information related to the shape and/or values of each of these said geometrical operators and assist the user in the interpretation and/or filtering process and in the identification of global and/or local maxima and minima in the values of said operators.

25. A computer program product comprising instructions which, when the program is executed by a computer, cause the computer to carry out the method of claim 1.
